(19) United States
(12) Patent Application Publication
(10) Pub. No.: US 2026/0371708 A1
(43) Pub. Date: Nov. 19, 2026

(54) SEMICONDUCTOR DEVICE

(71) Applicant: Micron Technology, Inc., Boise, ID (US)

(72) Inventor: Toshihiko Miyashita, Higashihiroshima (JP)

(73) Assignee: Micron Technology, Inc., Boise, ID (US)

(21) Appl. No.: 19/671,878

(22) Filed: May 8, 2026

Related U.S. Application Data
(60) Provisional application No. 63/808,472, filed on May 19, 2025.

(51) Int. Cl. H10D 84/83; H10D 84/85

(52) U.S. Cl. CPC H10D 84/8312; H10D 84/853

(57) ABSTRACT

An example apparatus includes a substrate and a first FinFET embedded in the substrate. The first FinFET including a gate electrode, one of source and drain and the other of source and drain. The one of source and drain comprises a Si-based compound and the other of source and drain comprises Si without the Si-based compound.

### CROSS-REFERENCE TO RELATED APPLICATIONS

This application claims the filing benefit of U.S. Provisional Application No. 63/808,472, filed May 19, 2025. This application is incorporated by reference herein in its entirety and for all purposes.

### BACKGROUND

For semiconductor devices exemplified by a dynamic random access memory (DRAM), attempts are being made to improve the performance of transistors constituting peripheral circuits for driving memory cells. Recently, there have been cases where fin-type metal-oxide-semiconductor field-effect transistors (MOSFETs) are used as transistors constituting DRAM peripheral circuits.

### BRIEF DESCRIPTION OF THE DRAWINGS

FIG. 1A is a plan view showing a schematic configuration of a semiconductor device according to an embodiment.

FIGS. 1B, 1C, 1D, and 1E are longitudinally sectional views showing a schematic configuration of the semiconductor device according to the embodiment.

FIG. 2A is a plan view showing a schematic configuration of the semiconductor device according to the embodiment.

FIGS. 2B and 2C are longitudinally sectional views showing a schematic configuration of the semiconductor device according to the embodiment.

FIG. 3A is a plan view showing a schematic configuration of the semiconductor device according to the embodiment.

FIG. 3B is a longitudinally sectional view showing a schematic configuration of the semiconductor device according to the embodiment.

FIG. 4A is a plan view showing a schematic configuration of the semiconductor device according to the embodiment.

FIG. 4B is a longitudinally sectional view showing a schematic configuration of the semiconductor device according to the embodiment.

FIGS. 5A, 5B, 5C, and 5D-13A, 13B, 13C, and 13D are diagrams showing a method for manufacturing a semiconductor device according to the embodiment in the order of steps and are longitudinally sectional views showing an example of a schematic configuration of an exemplary process stage.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

A semiconductor device according to an embodiment will be described below with reference to the drawings. In the following description, a dynamic random access memory (DRAM) will be described as an example of the semiconductor device. In the description of the embodiment, common or related elements, or substantially the same elements are given the same reference signs, and description thereof will be omitted. In the following drawings, the dimensions and dimensional ratios of respective parts in respective drawings may not necessarily match the dimensions and dimensional ratios in the embodiment. In the following description, an up-down direction and a left-right direction mean respective directions in each drawing when a semiconductor substrate is placed on a lower side.

High-voltage MOSFETs driven by a high power supply voltage of, for example, 3.2 volts, and low-voltage MOSFETs driven by a low power supply voltage of, for example, around 1.0 volts are used in a DRAM peripheral circuit. The high-voltage MOSFETs are used in peripheral circuits such as an I/O circuit and a sub-word driver circuit, for example. The low-voltage MOSFETs are used in, for example, an address decoder circuit, a sense amplifier circuit, and the like.

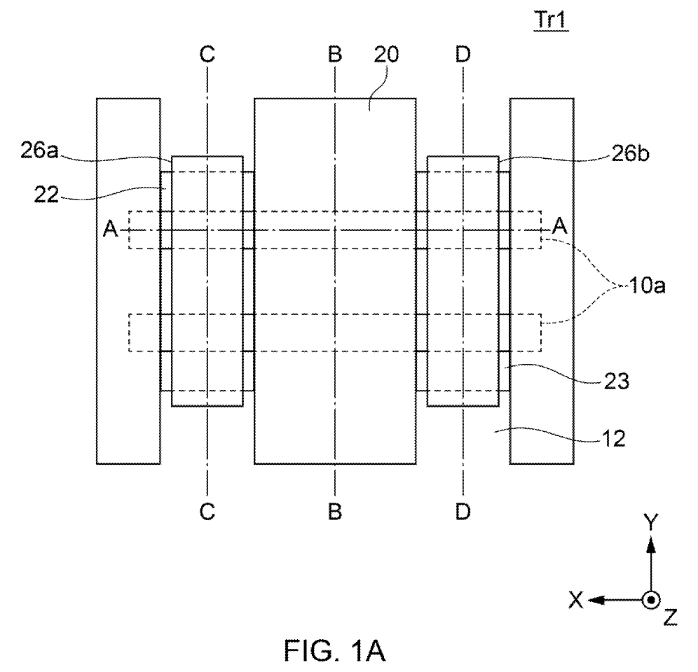

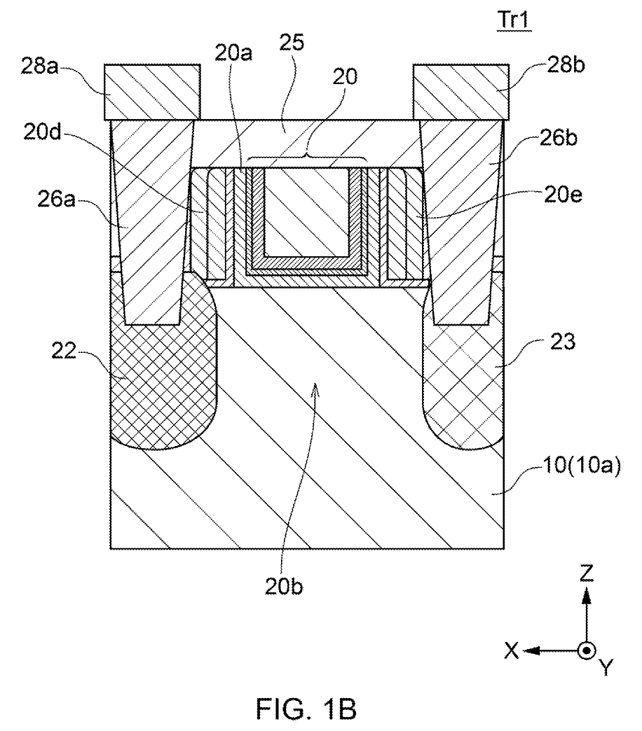

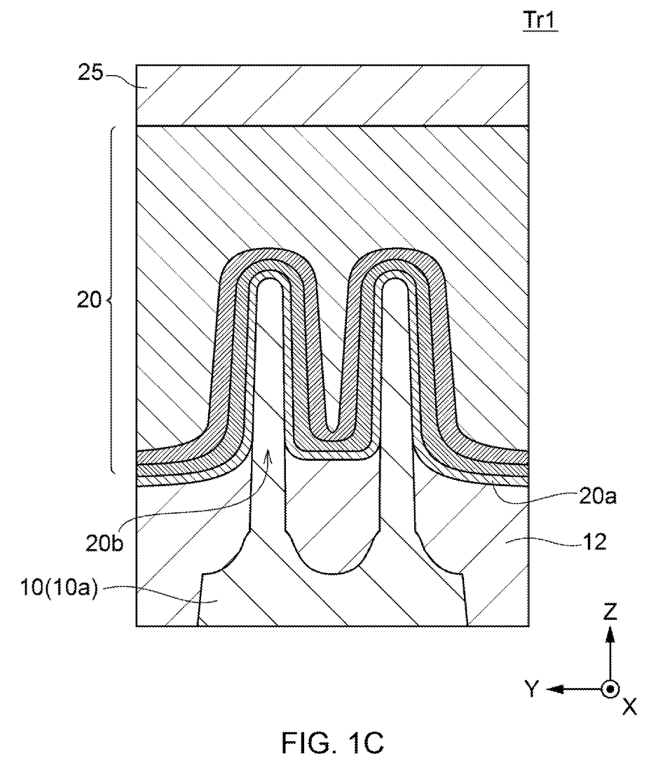

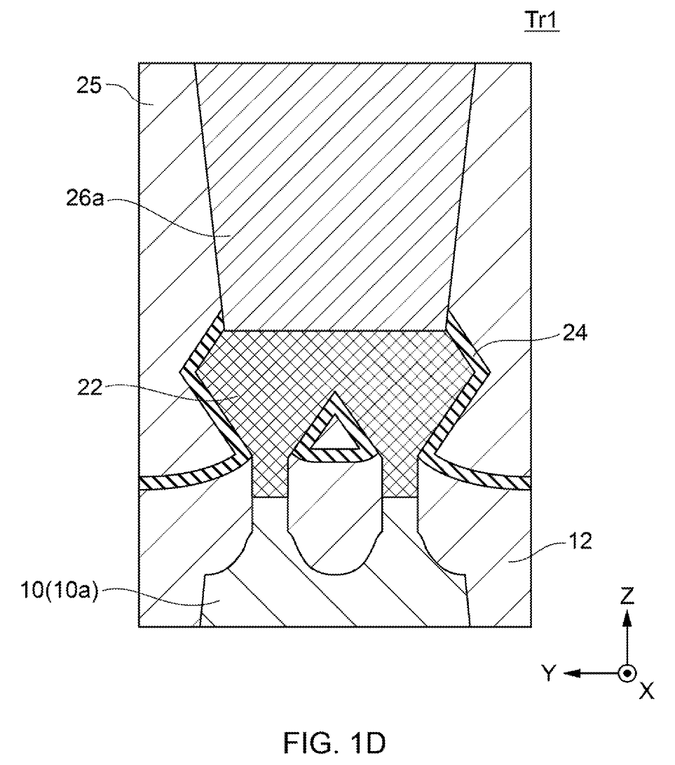

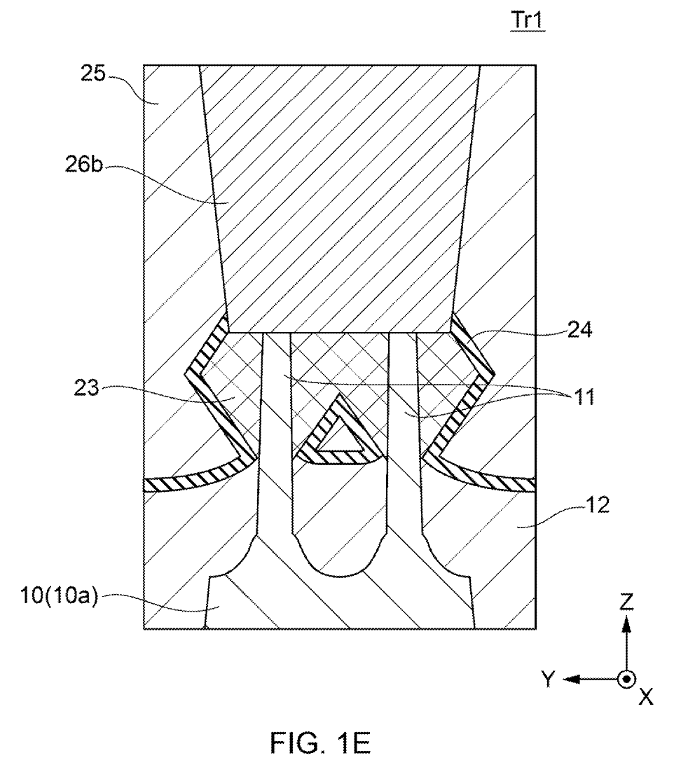

FIGS. 1A-1E, 2A-2C, 3A and 3B, and 4A and 4B are diagrams showing a schematic configuration of a laminated semiconductor device according to an embodiment, and show schematic configurations of respective fin-type MOSFETs (FinFET) constituting a DRAM peripheral circuit.

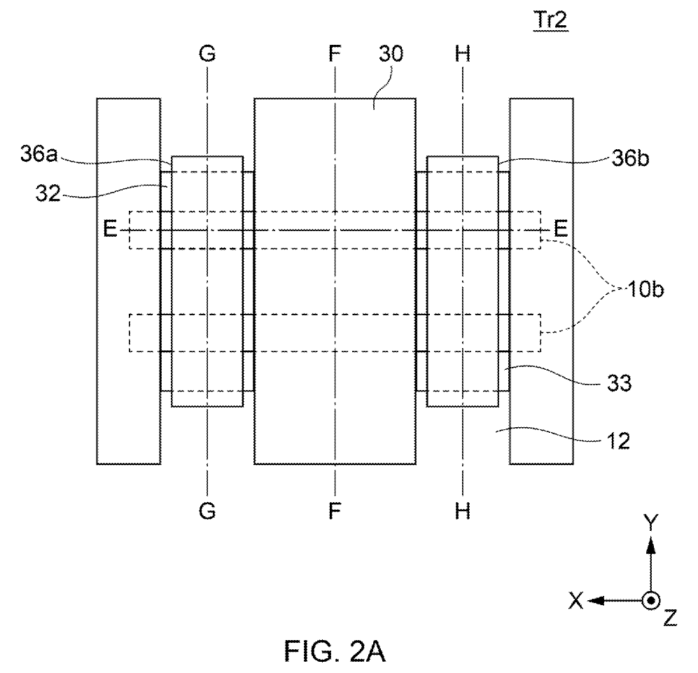

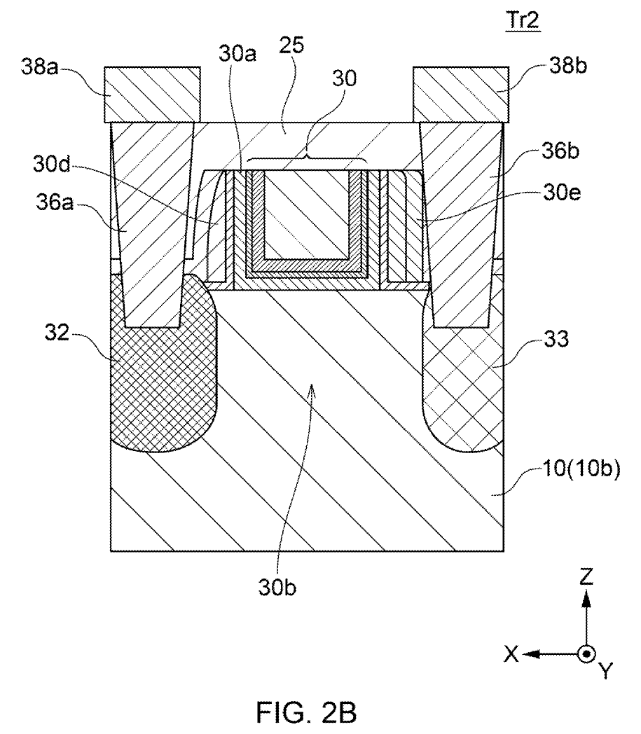

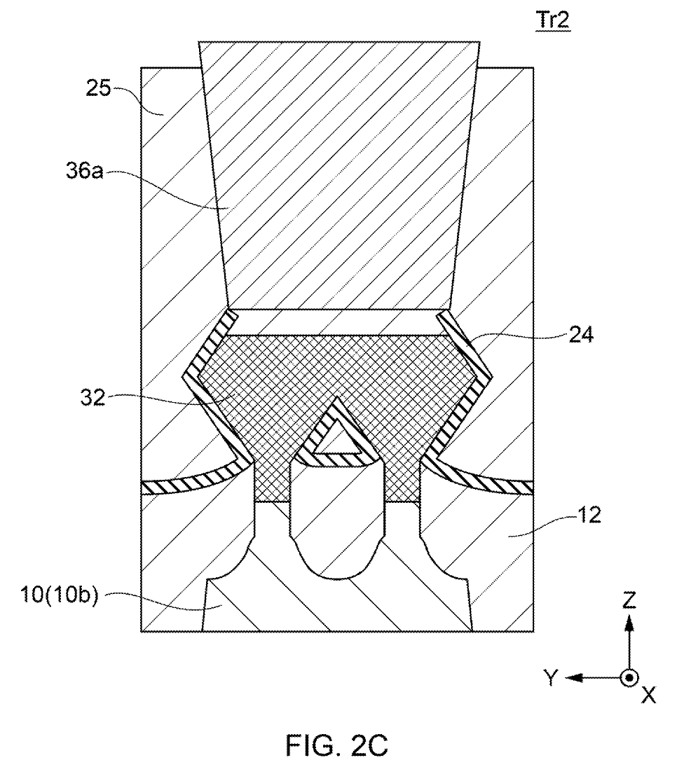

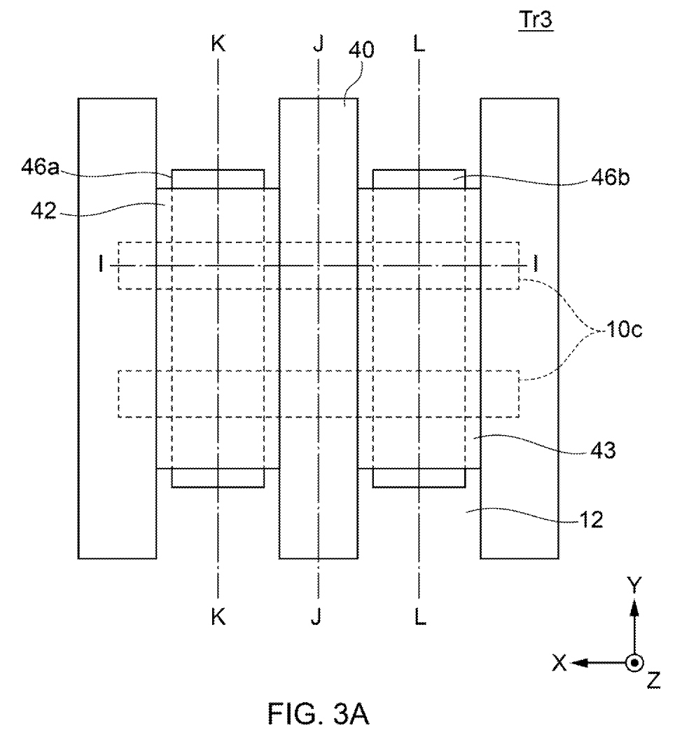

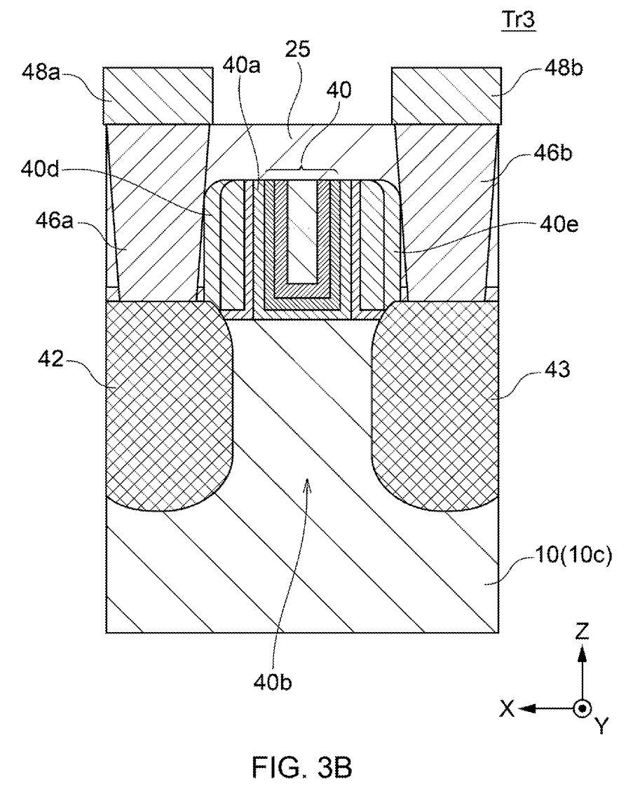

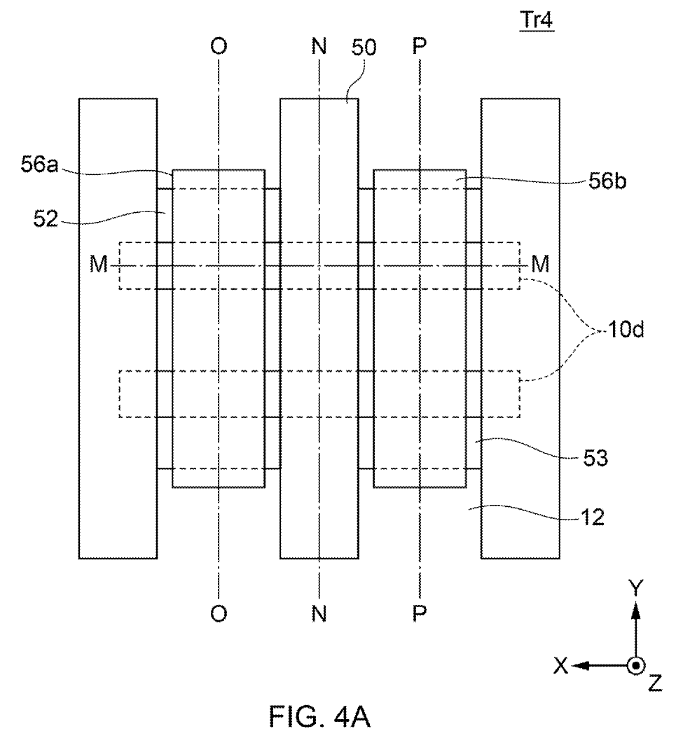

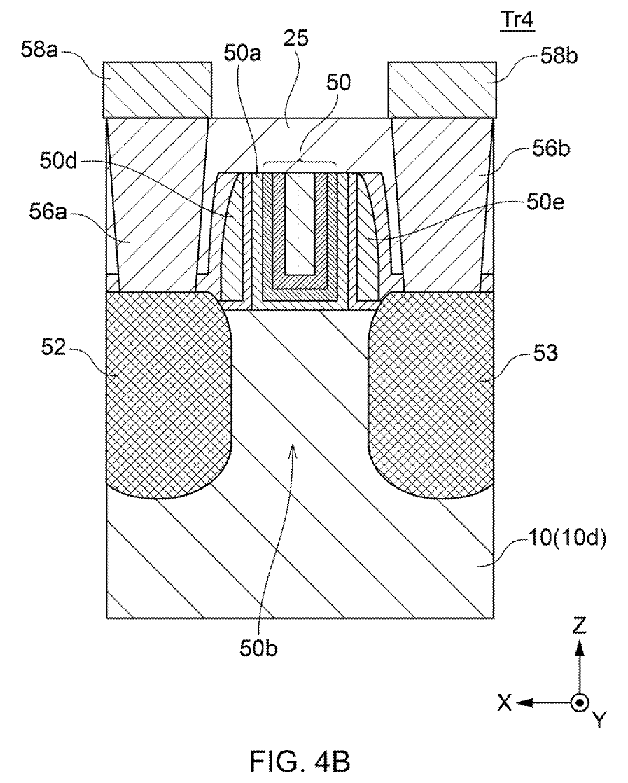

FIGS. 1A-1E show an example of a high voltage N-type MOSFET. The MOSFET shown in FIGS. 1A-1E is referred to as a first transistor Tr1. FIGS. 2A-2C show an example of a high voltage P-type MOSFET. The MOSFET shown in FIGS. 2A-2C is referred to as a second transistor Tr2. FIGS. 3A and 3B show an example of a low voltage N-type MOSFET. The MOSFET shown in FIGS. 3A and 3B is referred to as a third transistor Tr3. FIGS. 4A and 4B show an example of a low voltage P-type MOSFET. The MOSFET shown in FIGS. 4A and 4B is referred to as a fourth transistorTr4.

The first transistor Tr1, the second transistor Tr2, the third transistor Tr3, and the fourth transistor Tr4 of the semiconductor device according to the embodiment are FinFETs, and have a structure in which upper and side portions of each of fin-type active regions 10a, 10b, 10c, and 10d provided on a semiconductor substrate 10 are covered with gate electrodes 20, 30, 40, and 50, respectively. The FinFETs have device characteristics superior to planar MOSFETs in terms of ON-current, subthreshold characteristics, and the like.

First, the first transistor Tr1 shown in FIGS. 1A-1E will be described. FIG. 1A is a plan view. FIG. 1B is a longitudinally sectional view of a portion taken along a line A-A shown in FIG. 1A. FIG. 1C is a longitudinally sectional view of a portion taken along a line B-B shown in FIG. 1A. FIG. 1D is a longitudinally sectional view of a portion taken along a line C-C shown in FIG. 1A. FIG. 1E is a longitudinally sectional view of a portion taken along a line D-D shown in FIG. 1A.

The first transistor Tr1 includes an active region 10a, a gate electrode 20, a source region 22, a drain region 23, contact plugs 26a, 26b, and wirings 28a, 28b. The active region 10a is a region defined by an element isolation 12 provided in a semiconductor substrate 10, and has an island-like shape extending in an X-direction. Here, an example in which the first transistor Tr1 includes two active regions 10a is shown, but the number of active regions 10a is not limited to 2. The gate electrode 20 is disposed to be interposed between the source region 22 and the drain region 23, and the contact plugs 26a, 26b are connected to the source region 22 and the drain region 23, respectively.

The gate electrode 20 is disposed on the semiconductor substrate 10, and the source region 22 and the drain region 23 are provided on the semiconductor substrate 10 so as to interpose the gate electrode 20 therebetween. A channel portion 20b of the first transistor Tr1 is disposed between the source region 22 and the drain region 23 and below the gate electrode 20. A gate insulating film 20a is disposed between the gate electrode 20 and the semiconductor substrate 10, and sidewalls 20d and 20e are disposed on the side walls of the gate electrode 20. The contact plugs 26a and 26b are connected onto the source region 22 and the drain region 23, respectively. The wirings 28a and 28b are connected onto the contact plugs 26a and 26b, respectively.

The semiconductor substrate 10 includes, for example, single crystalline silicon. The gate electrode 20 includes, for example, a laminated structure of conductive materials such as tungsten (W), titanium nitride (TiN), and titanium aluminum carbon compound (TiAlC). The gate insulating film 20a includes an insulating material such as silicon dioxide (SiO₂), silicon nitride (SiN), hafnium oxide (HfO), or zirconium oxide (ZrO), for example. The sidewalls 20d and 20e include an insulating material such as a low-k film of SiOCN or the like, or silicon nitride, for example. The above-described matters also apply to the second transistor Tr2, the third transistor Tr3, and the fourth transistor Tr4 described later.

The source region 22 and the drain region 23 are substantially embedded in the semiconductor substrate 10, and the upper portions thereof are partially present on the semiconductor substrate 10. The source region 22 includes single crystal silicon which has been epitaxially grown while being doped in-situ with a high concentration of phosphorus. The impurity concentration of the source region 22 is, for example, about 0.5 to 5.0×10²¹ atms/cm³. The drain region 23 includes single crystal silicon doped with impurities such as phosphorus (P) or arsenic (As). A silicon pillar 11 is disposed at a center portion of the drain region 23. The silicon pillar 11 is a part of the semiconductor substrate 10, and serves as the active region 10a of the first transistor Tr1. The silicon pillar 11 extends in the X-direction in the figures, and has a columnar shape on a section in the Y-direction. The impurity concentration of the drain region 23 is, for example, about 1 to 5×10²⁰ atms/cm³. The impurity concentration of the source region 22 is higher than the impurity concentration of the drain region 23. The impurity concentration gradient at the end of the drain region 23 is gentler than the impurity concentration gradient at the end of the source region 22. The impurity concentration gradient at the end of the source region 22 is steeper than the impurity concentration gradient at the end of the drain region 23.

The upper sides of the gate electrode 20 and the sidewalls 20d and 20e on the upper surface of the semiconductor substrate 10 are covered with an interlayer insulating film 25. The contact plugs 26a and 26b penetrate the interlayer insulating film 25, and are connected to the source region 22, the drain region 23 and the wirings 28a, 28b, respectively. The interlayer insulating film 25 includes, for example, an insulating material such as silicon dioxide. The contact plugs 26a and 26b and the wirings 28a and 28b include a conductive material such as tungsten, for example.

Next, the second transistor Tr2 shown in FIGS. 2A-2C will be described. FIG. 2A is a plan view. FIG. 2B is a longitudinally sectional view of a portion taken along a line E-E shown in FIG. 2A. FIG. 2C is a longitudinally sectional view of a portion taken along a line G-G shown in FIG. 2A. Since the longitudinally sectional view of a portion taken along a line F-F shown in FIG. 2A is the same as FIG. 1C, and the longitudinally sectional view of a portion taken along a line H-H shown in FIG. 2A is the same as FIG. 1E, illustrations thereof are omitted.

An active region 10b, a gate electrode 30, a source region 32, a drain region 33, contact plugs 36a and 36b, and the wirings 38a and 38b are provided on a semiconductor substrate 10. A gate insulating film 30a is disposed between the gate electrode 30 and the semiconductor substrate 10, and sidewalls 30d and 30e are disposed on the side walls of the gate electrode 30. The source region 32 and the drain region 33 are substantially embedded in the semiconductor substrate 10, and the upper portions thereof are partially present on the semiconductor substrate 10. A channel portion 30b of the second transistor Tr2 is disposed between the source region 32 and the drain region 33 and below the gate electrode 30. The source region 32 includes single crystal SiGe obtained by epitaxially growing silicon germanium (SiGe) while boron is doped in-situ, for example. The germanium concentration is, for example, about 30 to 60 at%. The impurity concentration of the source region 32 is, for example, about 0.5 to 1.0×10²¹ atms/cm³. SiGe is an example of a Si-based compound. A compound containing an element having a larger atomic radius than Si, such as tin (Sn), may be used as the Si-based compound, for example. By growing crystals of these Si compounds larger than Si, compressive strain in a channel direction can be efficiently applied to a source-channel boundary by utilizing the difference in lattice constant.

The drain region 33 includes single crystal silicon doped with impurities such as boron. The impurity concentration of the drain region 33 is, for example, about 1 to 5×10²⁰ atms/cm³. The impurity concentration of the source region 32 is higher than that of the drain region 33. The impurity concentration gradient at the end of the drain region 33 is gentler than the impurity concentration gradient at the end of the source region 32. The impurity concentration gradient at the end of the source region 32 is steeper than the impurity concentration gradient at the end of the drain region 33. The other configurations are similar to those of the first transistor Tr1 described above.

Next, the third transistor Tr3 shown in FIGS. 3A and 3B will be described. FIG. 3A is a plan view. FIG. 3B is a longitudinally sectional view of a portion taken along a line I-I shown in FIG. 3A. Since the longitudinally sectional view of a portion taken along a line J-J shown in FIG. 3A is the same as FIG. 1C, and the longitudinally sectional views of a portion taken along a line K-K and a portion taken along a line L-L shown in FIG. 3A are the same as FIG. 1D, the illustrations thereof are omitted.

An active region 10c, a gate electrode 40, a source region 42, a drain region 43, contact plugs 46a and 46b, and wirings 48a and 48b are provided on a semiconductor substrate 10. A gate insulating film 40a is disposed between the gate electrode 40 and the semiconductor substrate 10, and sidewalls 40d and 40e are disposed on the side walls of the gate electrode 40. The source region 42 and the drain region 43 are substantially embedded in the semiconductor substrate 10, and the upper portions thereof are partially present on the semiconductor substrate 10. A channel portion 40b of the third transistor Tr3 is disposed between the source region 42 and the drain region 43 and below the gate electrode 40. The source region 42 and the drain region 43 include single crystal silicon which has been epitaxially grown while being doped in-situ with a high concentration of phosphorus or arsenic. The impurity concentrations of the source region 42 and the drain region 43 are, for example, about 0.5 to 5.0×10²¹ atms/cm³. The impurity concentrations of the source region 42 and the drain region 43 are high similarly to those of the source region 22 and the source region 32 described above, so that the impurity concentration gradients at the ends of the source region 42 and the drain region 43 are steep. The other configurations are the same as those of the transistors Tr1 and Tr2 described above.

Next, the fourth transistor Tr4 shown in FIGS. 4A and 4B will be described. FIG. 4A is a plan view. FIG. 4B is a longitudinally sectional view of a portion taken along a line M-M shown in FIG. 4A. Since the longitudinally sectional view of a portion taken along a line N-N shown in FIG. 4A is the same as FIG. 1C, and the longitudinally sectional views of a portion taken along a line O-O and a portion taken along a line P-P shown in FIG. 4A are the same as FIG. 2C, the illustrations thereof are omitted.

An active region 10d, a gate electrode 50, a source region 52, a drain region 53, contact plugs 56a and 56b, and wirings 58a and 58b are provided on a semiconductor substrate 10. A gate insulating film 50a is disposed between the gate electrode 50 and the semiconductor substrate 10, and sidewalls 50d and 50e are disposed on the side walls of the gate electrode 50. The source region 52 and the drain region 53 are substantially embedded in the semiconductor substrate 10, and the upper portions thereof are partially present on the semiconductor substrate 10. A channel portion 50b of the fourth transistor Tr4 is disposed between the source region 52 and the drain region 53 and below the gate electrode 50. The source region 52 and the drain region 53 include single crystal SiGe obtained by epitaxially growing SiGe while boron is doped in-situ. The germanium concentration is, for example, about 30 to 60 at%. The boron concentrations of the source region 52 and the drain region 53 are, for example, about 1×10²¹ atms/cm³. The boron concentrations in the source region 52 and the drain region 53 are high similarly to those in the source region 22 and the source region 32 described above, so that the impurity concentration gradients at the ends of the source region 52 and the drain region 53 are steep. The other configurations are similar to those of transistors Tr1 to Tr3 described above.

As described above, in the first transistor Tr1 which is an N-channel high-voltage MOSFET, the impurity concentration in the source region 22 is high, so that the sheet resistance and contact resistance of the source region 22 can be reduced. This makes it possible to improve the on-current of the first transistor Tr1. The impurity concentration in the drain region 23 is lower than that in the source region 22. However, the impurity concentration gradient at the end of the drain region 23 can be made gentle, so that it is possible to moderate the electric field in the channel direction at the end of the drain region 23 during operation of the first transistor Tr1. This makes it possible to restrain an increase in leakage current and deterioration in hot carrier caused by the steep junction of the first transistor Tr1, so that the device standby power and reliability can be improved.

In the second transistor Tr2 which is a P-channel high voltage MOSFET, the impurity concentration in the source region 32 is high, so that the sheet resistance and contact resistance of the source region 32 can be reduced. This makes it possible to improve the on-current of the second transistor Tr2. The impurity concentration in the drain region 33 is lower than that in the source region 32. However, since the impurity concentration gradient at the end of the drain region 33 can be made gentle, it is possible to moderate the electric field in the channel direction at the end of the drain region 33 when the second transistor Tr2 is driven. This makes it possible to restrain an increase in leakage current and deterioration in hot carrier caused by the steep junction of the second transistor Tr2. In addition, since the source region 32 includes single crystal SiGe, it is possible to improve the hole mobility of the channel portion 30b by the compressive strain of SiGe. This makes it possible to improve the device standby power and reliability of the second transistor Tr2. In addition, the compressive strain in the channel direction can be efficiently applied to the source end, and the mobility of carriers (holes) that cross the source barrier can be improved, thereby improving the device characteristics.

In the third transistor Tr3 which is an N-channel low voltage MOSFET and the fourth transistor Tr4 which is a P-channel low voltage MOSFET, the impurity concentrations in the source regions 42, 52 and the drain regions 43, 53 are high, so that the sheet resistance and contact resistance of the source regions 42, 52 and the drain regions 43, 53 can be reduced. This makes it possible to improve the on-currents of the third transistor Tr3 and the fourth transistor Tr4. Furthermore, the impurity concentration gradients at the ends of the drain regions 43, 53 are steep. However, the third transistor Tr3 and the fourth transistor Tr4 are low voltage MOSFETs that are driven at a low voltage. Therefore, the electric field in the channel direction at the ends of the drain regions 43, 53 when the third transistor Tr3 and the fourth transistor Tr4 are driven is weak. Therefore, in the third transistor Tr3 and the fourth transistor Tr4, the increase in leakage current and deterioration in hot carrier caused by the steep junction are restrained, and deterioration of the device standby power characteristics and reliability is restrained.

Furthermore, in the fourth transistor Tr4, since the source region 52 includes single crystal SiGe, the hole mobility in the channel portion 50b can be enhanced by the compressive strain of SiGe. This makes it possible to further improve the device performance and reliability of the fourth transistor Tr4.

Next, an outline of a method for manufacturing the semiconductor device according to the embodiment will be described with reference to FIGS. 5A, 5B, 5C, and 5D-13A, 13B, 13C, and 13D to FIGS. 13A, 13B, 13C, and 13D, FIGS. 1A-1E, 2A-2C, 3A and 3B, and 4A and 4B.

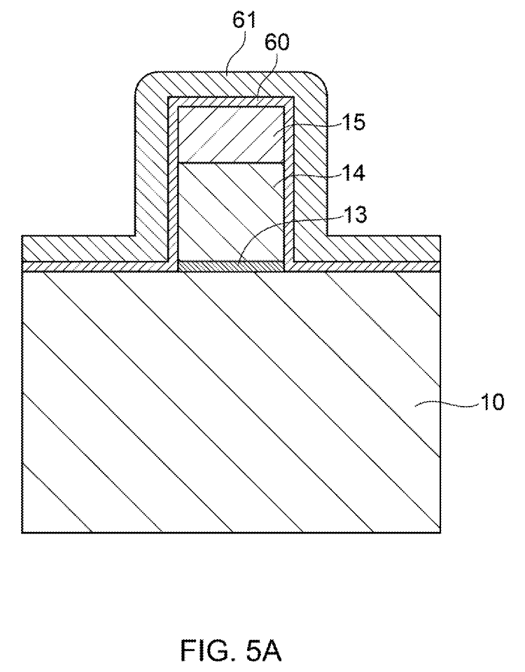

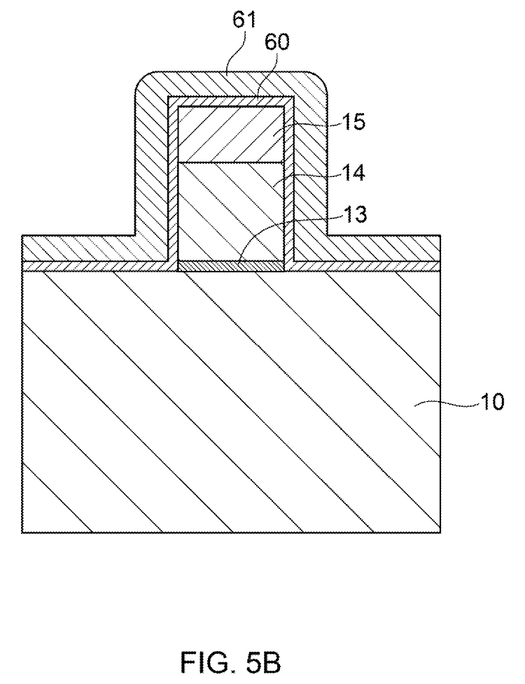

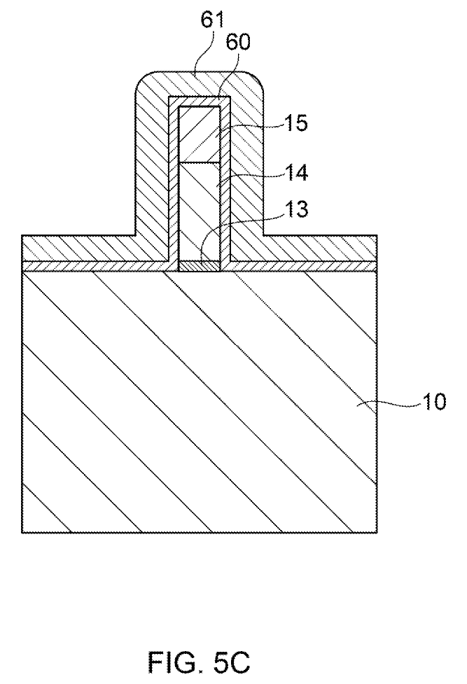

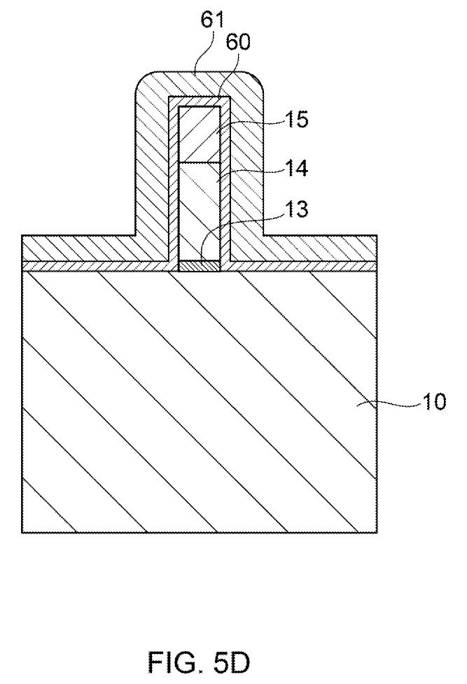

FIGS. 5A-13A show a schematic configuration of a formation region of the first transistor Tr1 shown in FIG. 1B described above. FIGS. 5B-13B show a schematic configuration of a formation region of the second transistor Tr2 shown in FIG. 2B described above. FIGS. 5C-13C show a schematic configuration of a formation region of the third transistor Tr3 shown in FIG. 3B described above. FIGS. 5D-13D show a schematic configuration of a formation region of the fourth transistor Tr4 shown in FIG. 4B described above.

First, as shown in FIGS. 5A-5D, a dummy insulating film 13, a dummy gate 14, and a dummy cap 15 are formed on a semiconductor substrate 10. Regions where the dummy insulating film 13, the dummy gate 14, and the dummy cap 15 are formed ultimately become regions where the gate insulating films and gate electrodes of the transistors Tr1 to Tr4 will be formed. The dummy insulating film 13, the dummy gate 14, and the dummy cap 15 can be formed by forming films of silicon dioxide, polysilicon, and silicon nitride, for example, in this order using Chemical Vapor Deposition (CVD), and then applying a known lithography technique and an anisotropic dry etching technique.

Next, a first insulating film 60 and a second insulating film 61 are formed using CVD so as to cover the upper surface of the semiconductor substrate 10, the dummy gate 14, and the dummy cap 15. The first insulating film 60 contains, for example, silicon dioxide, and the second insulating film 61 contains, for example, silicon nitride.

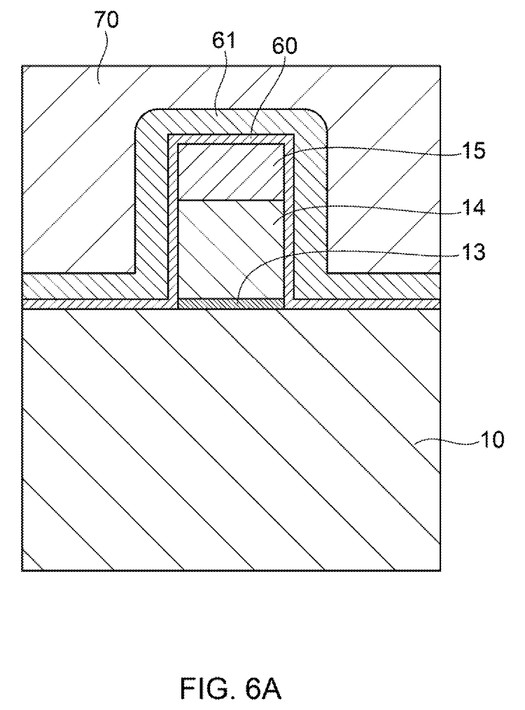

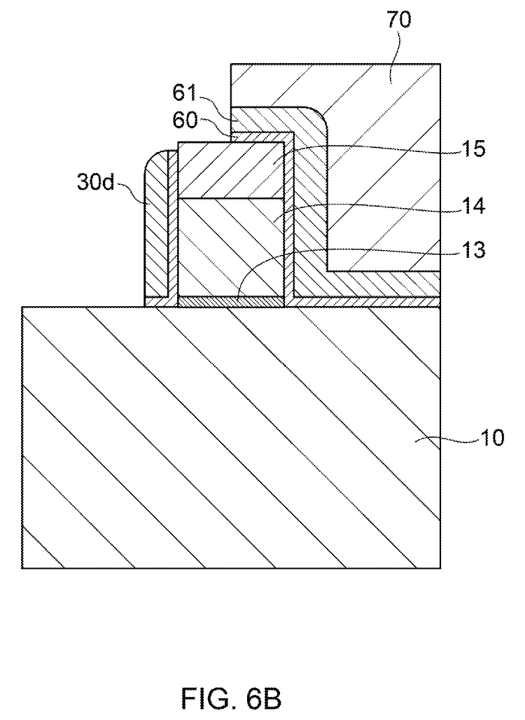

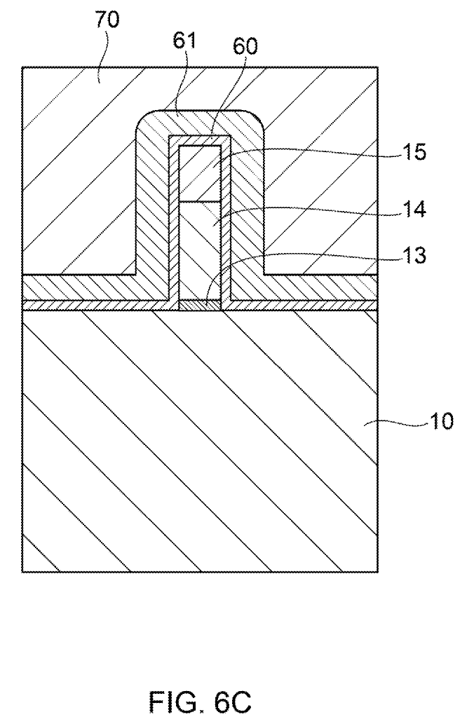

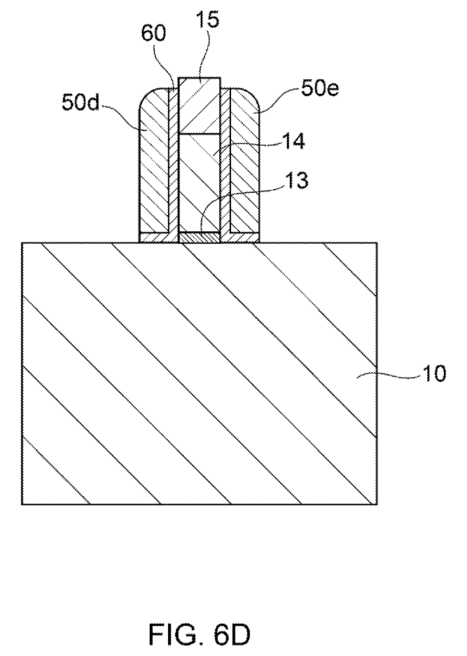

Next, as shown in FIGS. 6A-6D, a first resist 70 is formed by using a known lithography technique, and then the first insulating film 60 and the second insulating film 61 are etched with the first resist 70 as a mask by using an anisotropic dry etching technique. As shown in FIGS. 6B and 6D, the first resist 70 is opened on the source region side above the dummy cap 15 of the second transistor Tr2, in the source region of the second transistor Tr2, and the formation region of the fourth transistor Tr4. The formation region of the first transistor Tr1 shown in FIG. 6A and the formation region of the third transistor Tr3 shown in FIG. 6C are covered with the first resist 70. The first insulating film 60 and the second insulating film 61 in the opening portion are etched by anisotropic dry etching, and a Tr2 first sidewall 30d, a Tr4 first sidewall 50d, and a Tr4 second sidewall 50e are formed. The Tr2 first sidewall 30d, the Tr4 first sidewall 50d, and the Tr4 second sidewall 50e have a laminated structure of the first insulating film 60 and the second insulating film 61.

The Tr2 first sidewall 30d is formed on the side surfaces of the dummy gate 14 and the dummy cap 15 on the source region side in the formation region of the second transistor Tr2. The Tr4 first sidewall 50d and the Tr4 second sidewall 50e are formed on side surfaces on both the sides of the dummy gate 14 and the dummy cap 15 in the formation region of the fourth transistor Tr4. The top surfaces of the semiconductor substrate 10 in the source region of the second transistor Tr2 shown in FIG. 6B and the source region and drain region of the fourth transistor Tr4 shown in FIG. 6D are exposed.

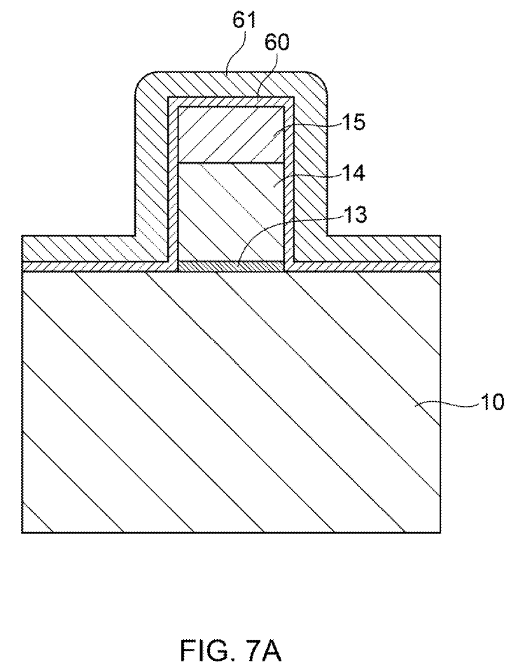

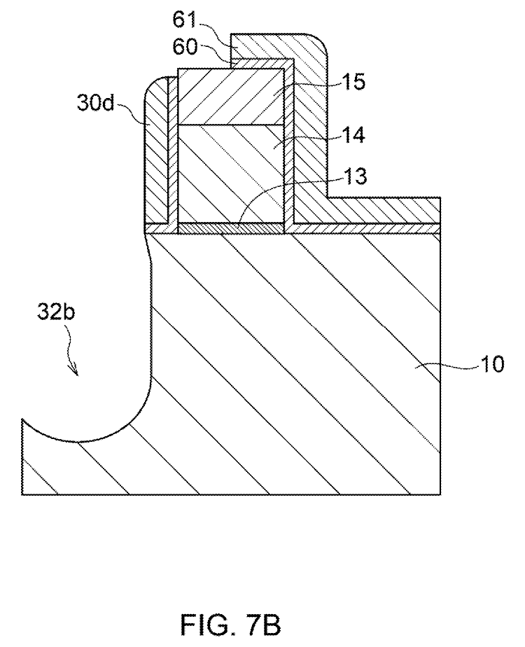

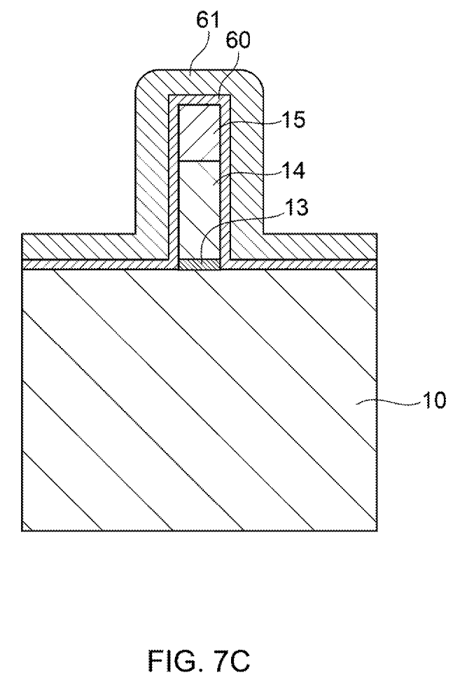

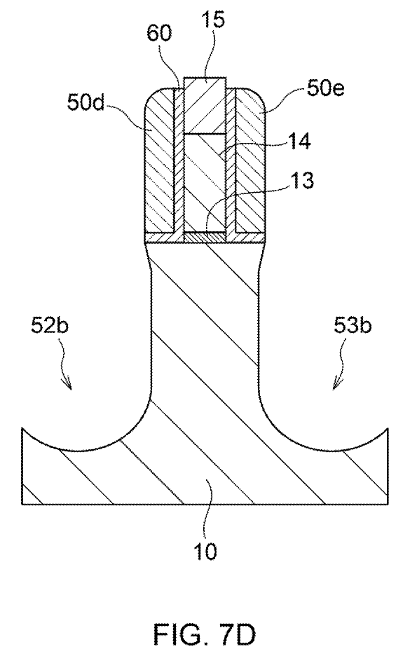

Next, as shown in FIGS. 7A-7D, after the first resist 70 is removed, anisotropic dry etching is performed using the second insulating film 61, the dummy cap 15, the Tr2 first sidewall 30d, the Tr4 first sidewall 50d, and the Tr4 second sidewall 50e as masks. This anisotropic dry etching is performed under the condition that the etching rates of silicon and silicon dioxide are greater than the etching rate of silicon nitride.

This anisotropic dry etching etches the semiconductor substrate 10 and the element isolation 12 in the region indicated by the source region 32 in FIG. 2A and the region indicated by the source region 52 in FIG. 4A to form a source region trench 32b, a source region trench 52b, and a drain region trench 53b. The silicon surface of the semiconductor substrate 10 is exposed in the trenches 32b, 52b, and 53b.

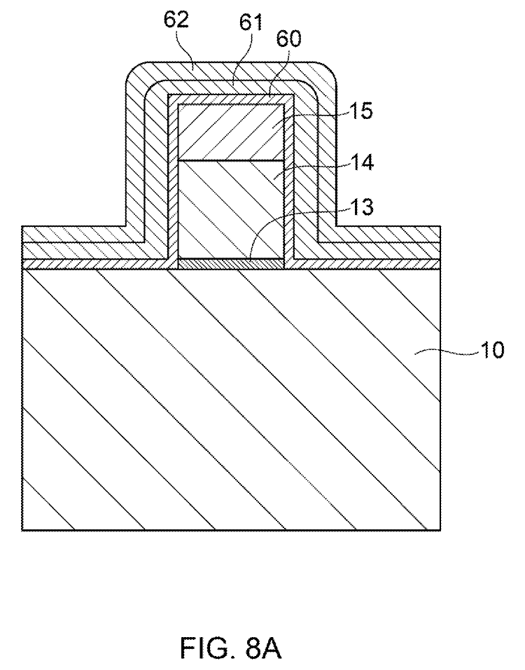

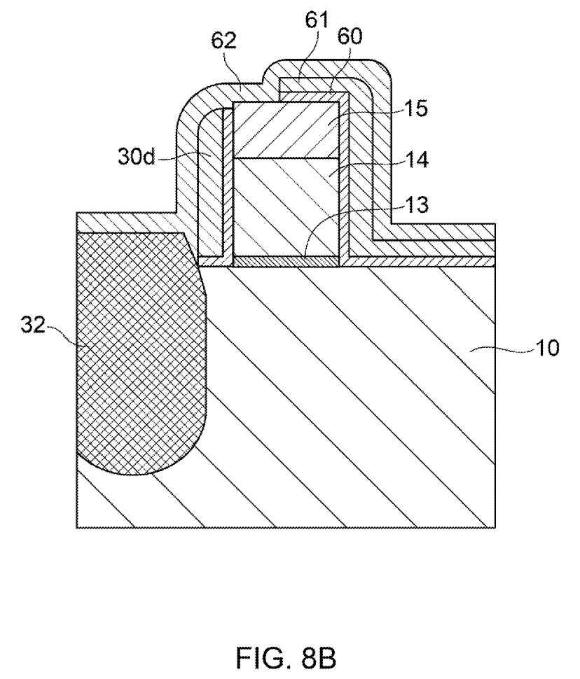

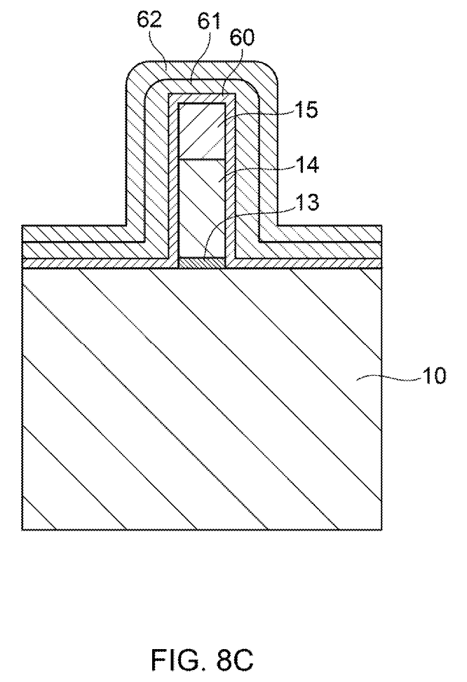

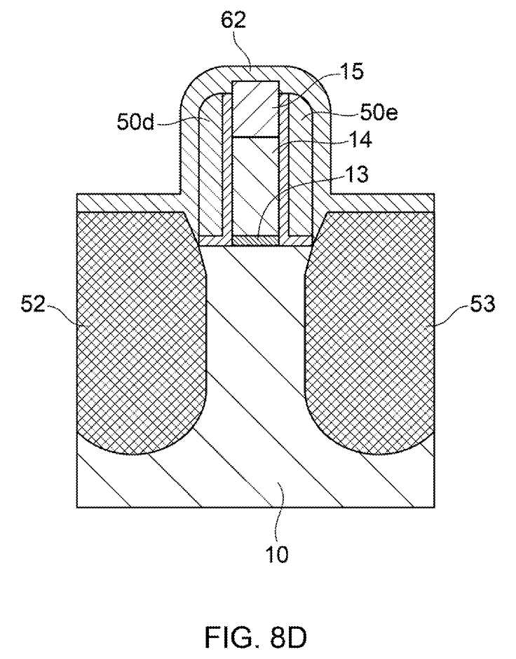

Next, as shown in FIGS. 8A-8D, the silicon surfaces exposed in the source region trench 32b, the source region trench 52b, and the drain region trench 53b are used as seed crystals to selectively form single crystal SiGe, thereby forming the source region 32 of the second transistor Tr2, and the source region 52 and drain region 53 of the fourth transistor Tr4.

SiGe is formed using selective epitaxial growth (SEG). The following processing is performed in the SEG of SiGe. The semiconductor substrate 10 is placed in a process chamber, the pressure is adjusted to, for example, 0.1 Torr to 200 Torr, the temperature is adjusted to, for example, 500°C to 900°C, and a source gas is supplied. Silane (SiH₄) or dichlorosilane (SiH₂Cl₂), and digermane (GeH₄) or the like are used as the source gas. H₂, N₂, Ar, He or the like is used as a carrier gas. A dopant gas such as diborane (B₂H₆) is introduced during the film formation of the SiGe, and boron is doped in-situ into the SiGe. The use of In-situ doping allows the dopant to be doped at a high concentration. Boron is doped at a concentration of, for example, about 1×10²¹ atoms/cm³. Through the above steps, trenches 32b, 52b, and 53b are embedded in boron-doped single-crystal SiGe. Through the above steps, in-situ boron-doped SEG SiGe is formed in the source region 32, the source region 52, and the drain region 53. Facets of single-crystal SiGe are formed in the source region 32, the source region 52, and the drain region 53.

Next, a third insulating film 62 is formed so as to cover the upper surface of the semiconductor substrate 10 containing SiGe. The third insulating film 62 contains an insulating material such as silicon nitride, and is formed by CVD.

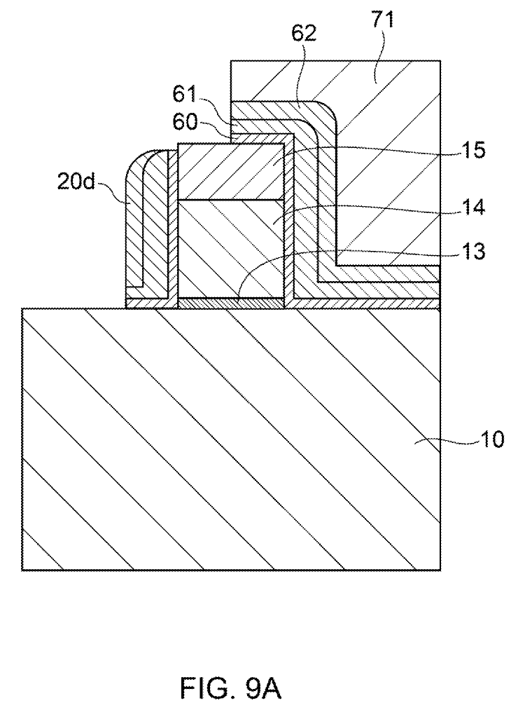

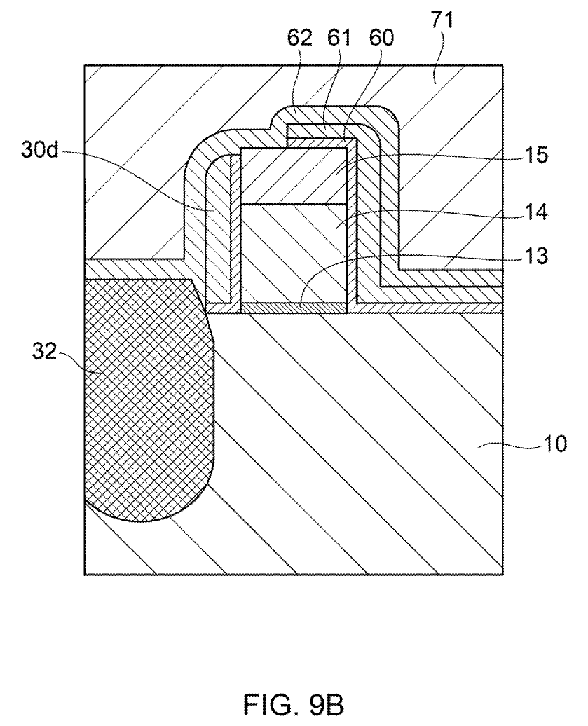

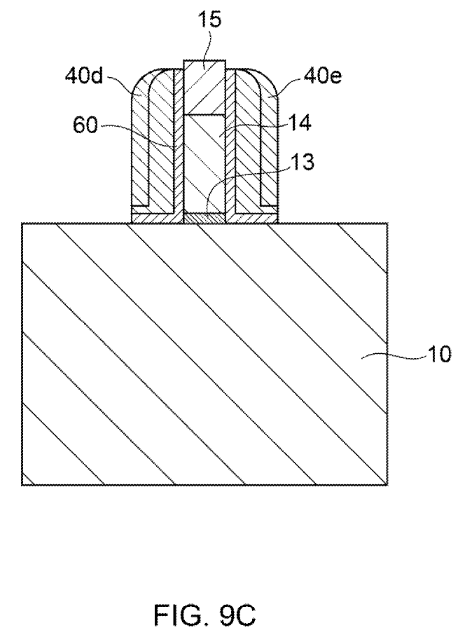

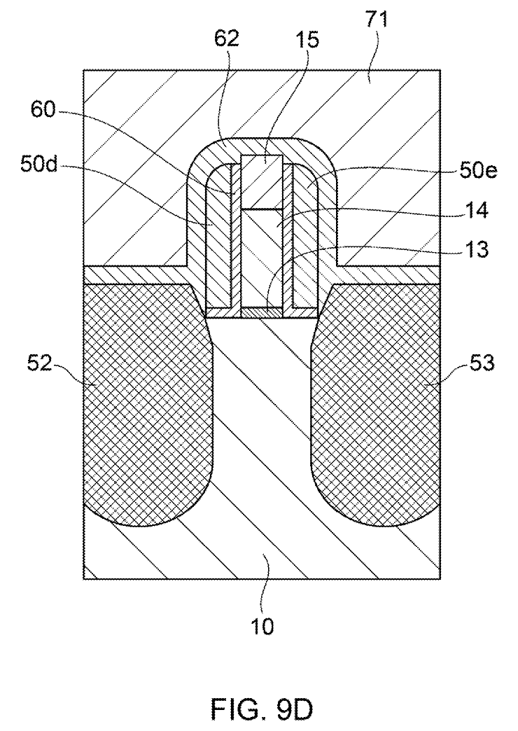

Next, as shown in FIGS. 9A-9D, a second resist 71 is formed using a known lithography technique, and then, the third insulating film 62, the second insulating film 61, and the first insulating film 60 are etched using the second resist 71 as a mask by an anisotropic dry etching technique. As shown in FIGS. 9A and 9C, the second resist 71 is opened on the source region side above the dummy cap 15 of the first transistor Tr1, in the source region of the first transistor Tr1, and in the formation region of the third transistor Tr3. The formation region of the second transistor Tr2 shown in FIG. 9B and the formation region of the fourth transistor Tr4 shown in FIG. 9D are covered by the second resist 71.

The third insulating film 62, the second insulating film 61, and the first insulating film 60 in the opening portion are etched by anisotropic dry etching to form a Tr1 first sidewall 20d, a Tr3 first sidewall 40d, and a Tr3 second sidewall 40e. The Tr1 first sidewall 20d, the Tr3 first sidewall 40d, and the Tr3 second sidewall 40e have a laminated structure of the third insulating film 62, the second insulating film 61, and the first insulating film 60. The Tr1 first sidewall 20d is formed on the side surfaces on both the source region sides of the dummy gate 14 and the dummy cap 15 in the formation region of the first transistor Tr1. The Tr3 first sidewall 40d and the Tr3 second sidewall 40e are formed on the side surface on both sides of the dummy gate 14 and the dummy cap 15 in the formation region of the third transistor Tr3. The upper surfaces of the semiconductor substrate 10 in the source region of the first transistor Tr1 shown in FIG. 9A and in the source region and drain region of the third transistor Tr3 shown in FIG. 9C are exposed.

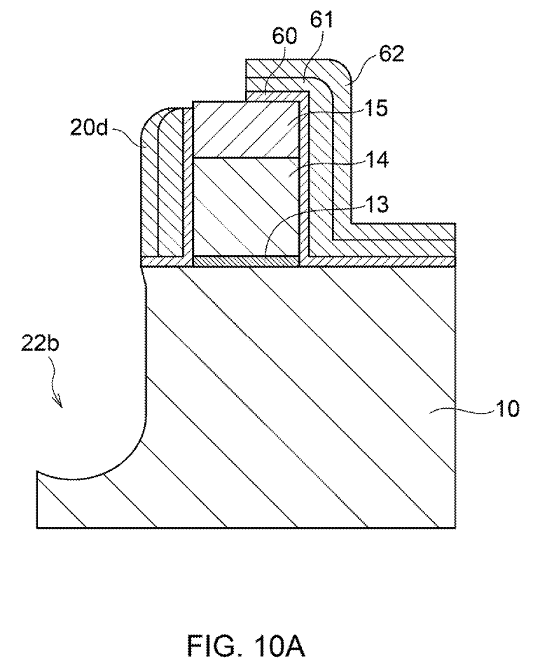

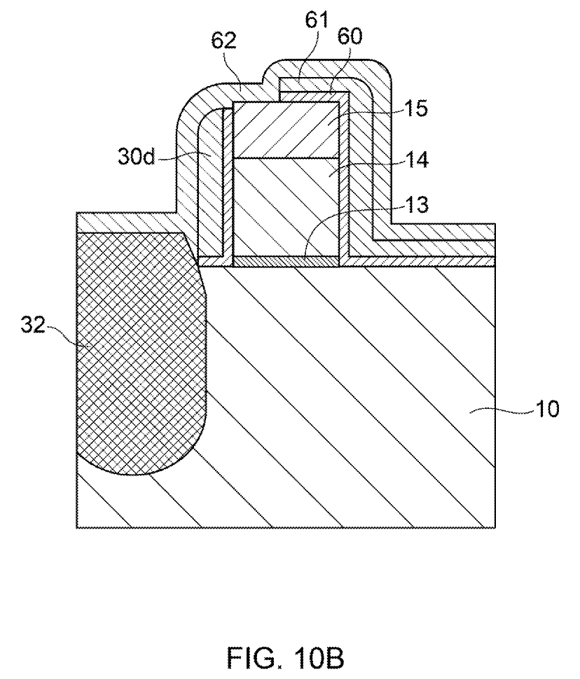

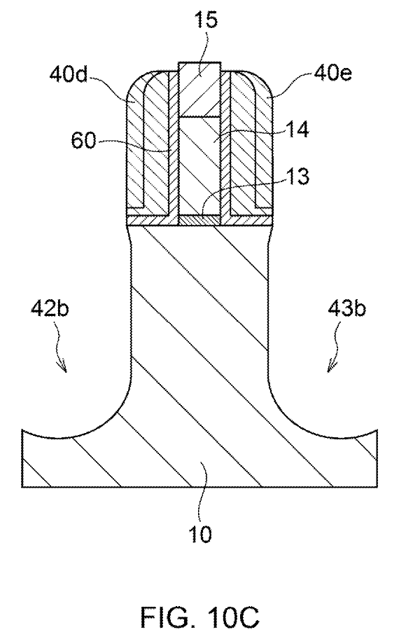

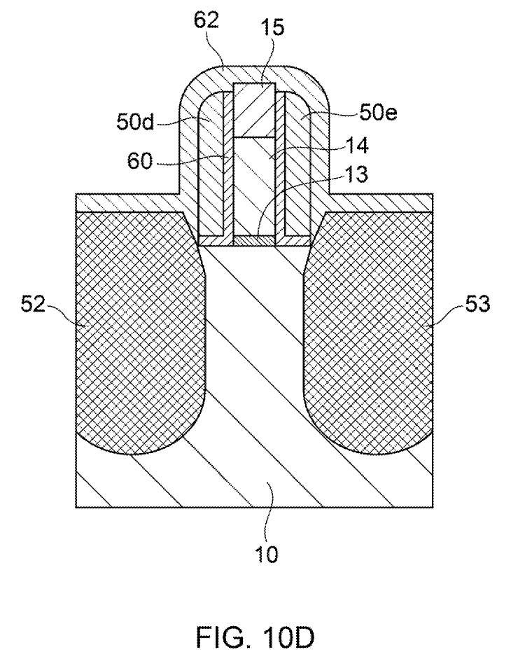

Next, as shown in FIGS. 10A-10D, anisotropic dry etching is performed using the third insulating film 62, the dummy cap 15, the Tr1 first sidewall 20d, the Tr3 first sidewall 40d, and the Tr3 second sidewall 40e as masks. This anisotropic dry etching is performed under the condition that the etching rates of silicon and silicon dioxide are greater than the etching rate of silicon nitride. This anisotropic dry etching forms a source region trench 22b, a source region trench 42b, and a drain region trench 43b in the semiconductor substrate 10 and the element isolation 12 in the region indicated by the source region 22 in FIG. 1A and the regions indicated by the source region 42 and the drain region 43 in FIG. 3A. The silicon surface of the semiconductor substrate 10 is exposed in the trenches 22b, 42b, and 43b.

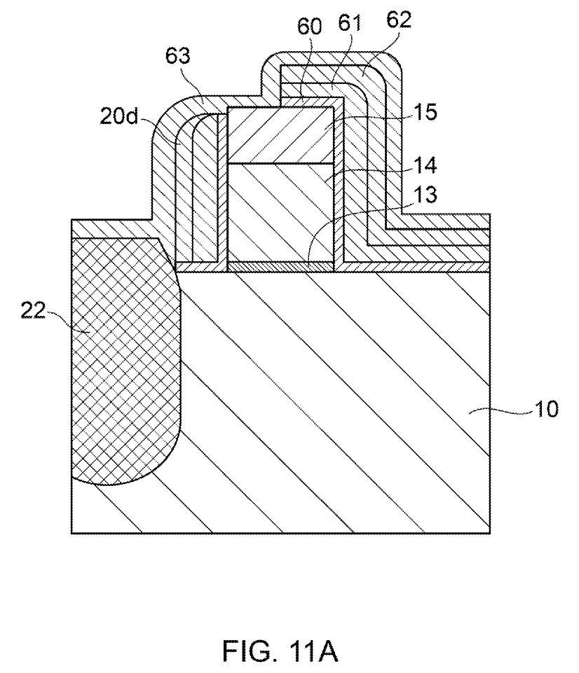

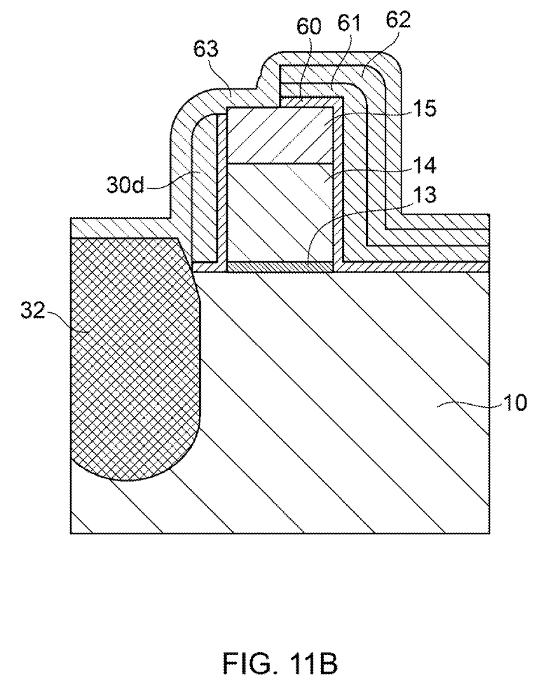

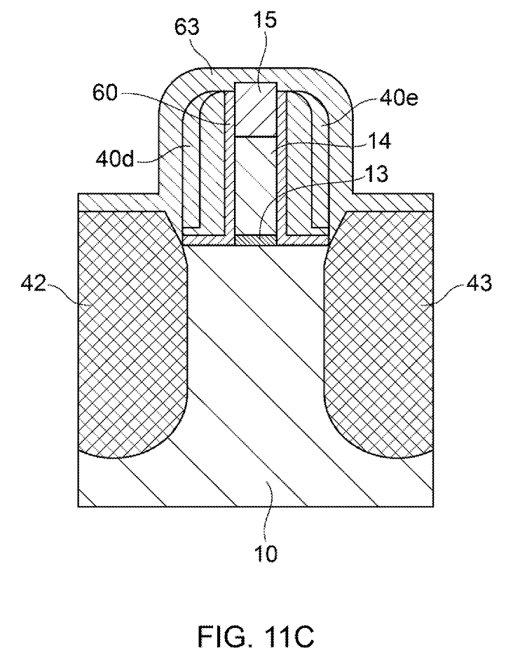

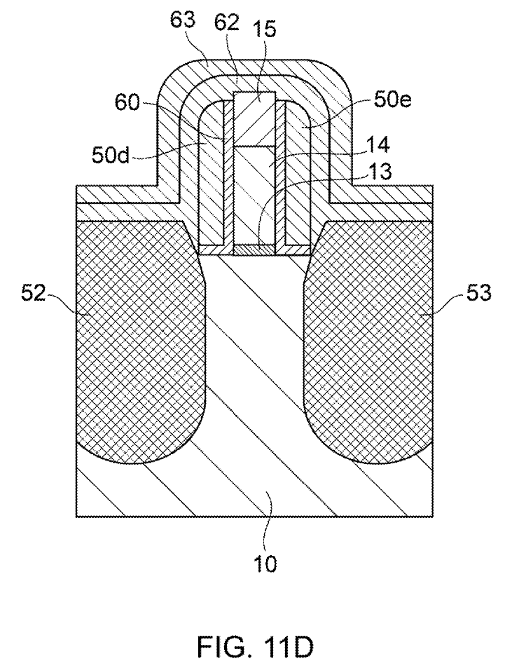

Next, as shown in FIGS. 11A-11D, the silicon surfaces exposed in the source region trench 22b, the source region trench 42b, and the drain region trench 43b are used as seed crystals to selectively form single crystal Si, thereby forming the source region 22 of the first transistor Tr1, and the source region 42 and the drain region 43 of the third transistor Tr3.

Si is formed using SEG. The following processing is performed in the SEG of Si. The semiconductor substrate 10 is placed in a processing chamber, and a source gas is supplied. Silane (SiH₄), dichlorosilane (SiH₂Cl₂) or the like is used as the source gas. The conditions for the pressure, the temperature, and the carrier gas are the same as those in the SEG described above. A dopant gas such as phosphine (PH₃) is introduced during the film formation of Si, and phosphorus is doped in-situ into Si. By using in-situ doping, the dopant can be doped at a high concentration. Phosphorus is doped at a concentration of, for example, about 1×10²¹ atoms/cm³.

Through the above steps, phosphorus-doped single crystal Si is embedded in the trenches 22b, 42b, and 43b. As described above, the in-situ phosphorus-doped SEG Si is formed in the source region 22, the source region 42, and the drain region 43. Facets of single crystal Si are formed in the source region 22, the source region 42, and the drain region 43. Here, Si may be doped with arsenic. Next, a fourth insulating film 63 is formed so as to cover the upper surface of the semiconductor substrate 10 including the formed single crystal Si. The fourth insulating film 63 contains an insulating material such as silicon nitride, and is formed by CVD.

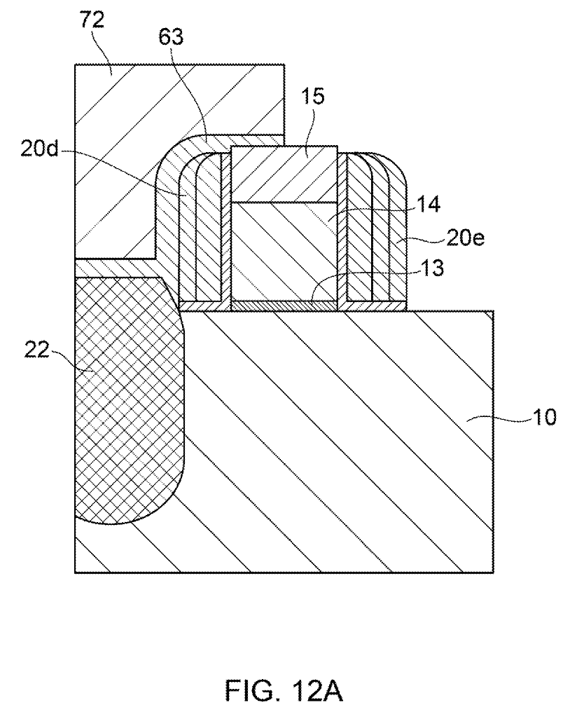

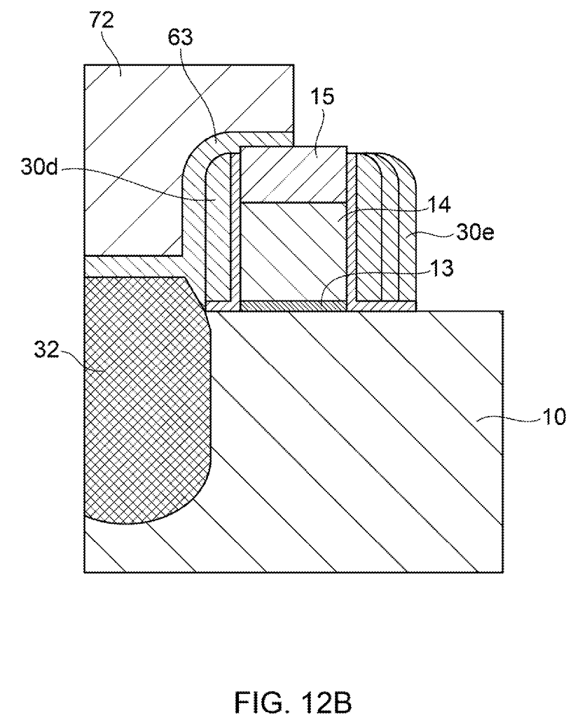

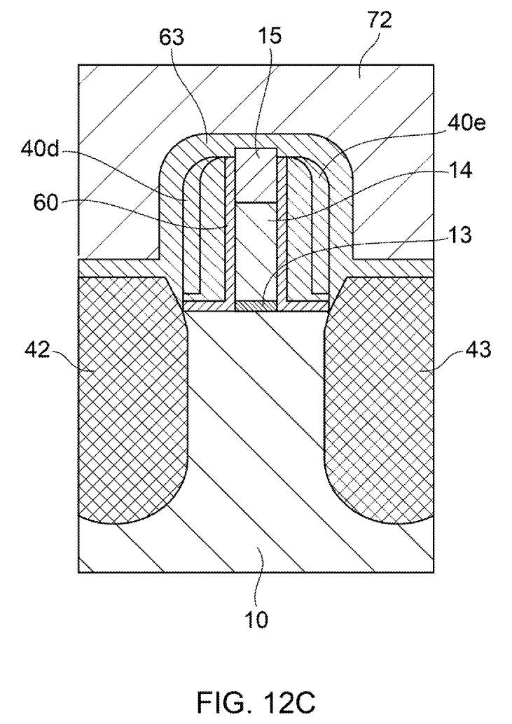

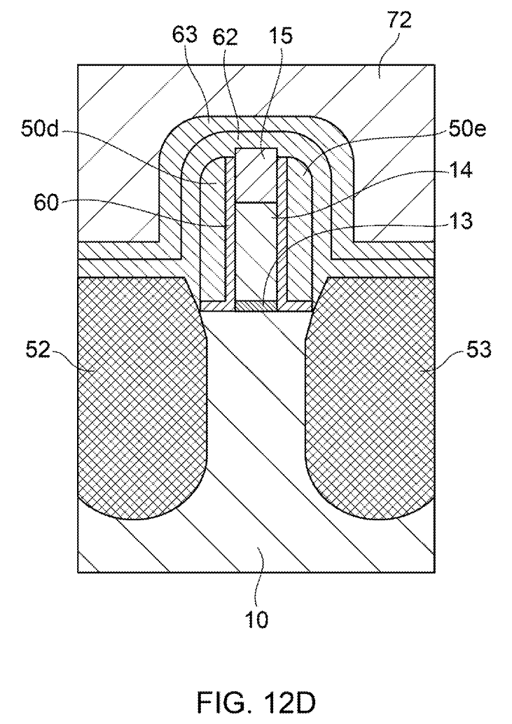

Next, as shown in FIGS. 12A-12D, a third resist 72 is formed by using a known lithography technique, and then the fourth insulating film 63, the third insulating film 62, the second insulating film 61, and the first insulating film 60 are etched using the third resist 72 as a mask by anisotropic dry etching technique. As shown in FIGS. 12A and 12B, the third resist 72 is opened on the drain region side above the dummy cap 15 of the first transistor Tr1 and in the drain region of the first transistor Tr1, and on the drain region side above the dummy cap 15 of the second transistor Tr2 and in the drain region of the second transistor Tr2. The formation region of the third transistor Tr3 shown in FIG. 12C and the formation region of the fourth transistor Tr4 shown in FIG. 12D are covered with the third resist 72.

The fourth insulating film 63, the third insulating film 62, the second insulating film 61, and the first insulating film 60 in the opening portion are etched by anisotropic dry etching to form the Tr1 second sidewall 20e and the Tr2 second sidewall 30e. The Tr1 second sidewall 20e and the Tr2 second sidewall 30e have a laminated structure of the fourth insulating film 63, the third insulating film 62, the second insulating film 61, and the first insulating film 60. The Tr1 second sidewall 20e is formed on the side surfaces on the drain region sides of the dummy gate 14 and the dummy cap 15 in the formation region of the first transistor Tr1. The Tr2 second sidewall 30e is formed on the side surfaces on the drain region sides of the dummy gate 14 and the dummy cap 15 in the formation region of the second transistor Tr2. The upper surfaces of the semiconductor substrate 10 in the drain region of the first transistor Tr1 shown in FIG. 12A and the drain region of the second transistor Tr2 shown in FIG. 12B are exposed.

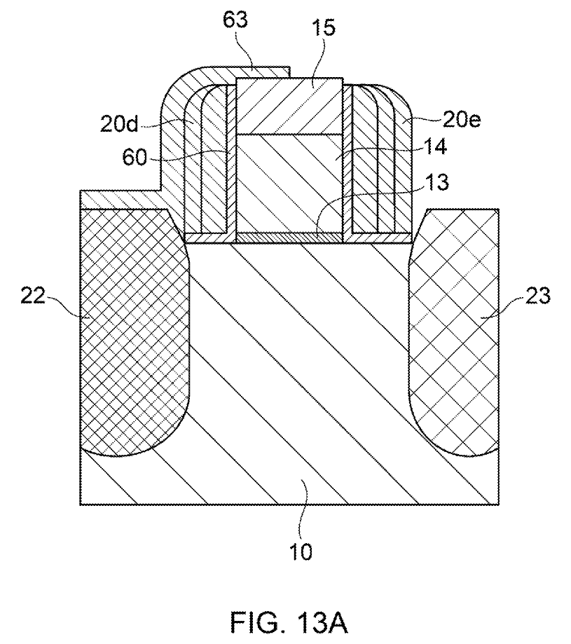

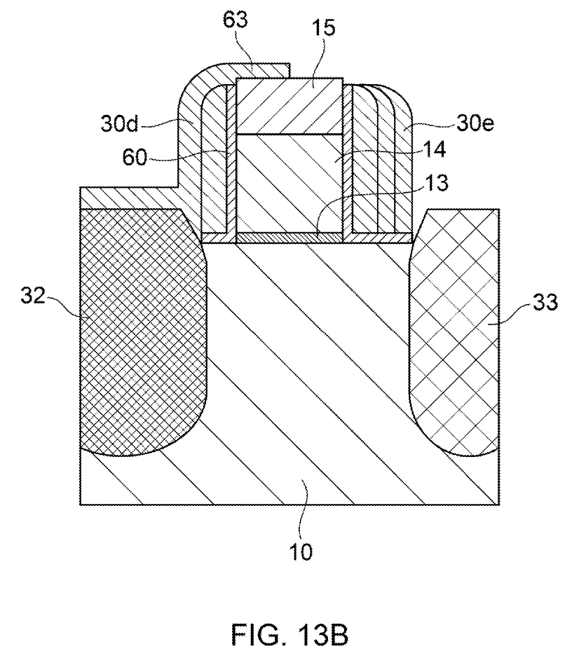

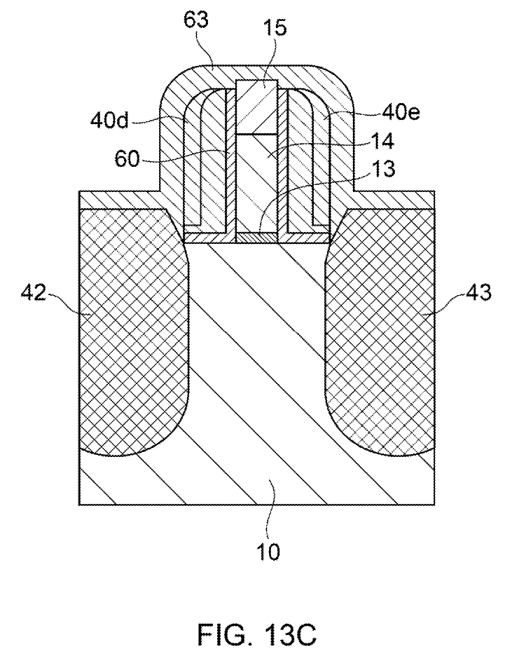

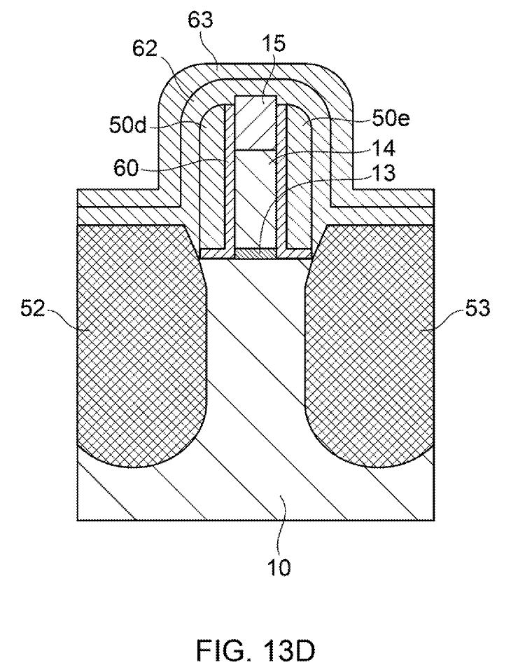

Next, as shown in FIGS. 13A-13D, after the third resist 72 is removed, anisotropic dry etching is performed using the fourth insulating film 63, the dummy cap 15, the Tr1 second sidewall 20e, and the Tr3 second sidewall 40e as masks to form trenches in the element isolation 12 in the region indicated by the drain region 23 in FIG. 1A and the region indicated by the drain region 33 in FIG. 2A. This anisotropic dry etching is performed under the condition that the etching rate of silicon dioxide is greater than the etching rates of silicon nitride and silicon. This anisotropic dry etching forms the silicon pillar 11 in each of the active regions 10a and 10b in the regions indicated by the drain region 23 and the drain region 33 in FIGS. 1A and 2A. Since the silicon pillars 11 are the semiconductor substrate 10, single crystal silicon is exposed on the surfaces of the silicon pillars 11.

Thereafter, the drain region 23 of the first transistor Tr1 and the drain region 33 of the third transistor Tr3 are formed by selectively forming single crystal Si in the trench. The single crystal Si is formed by using SEG. The single crystal Si is selectively formed on the silicon pillar 11 so as to surround the silicon pillar 11 using silicon exposed on the surface of the silicon pillar 11 as a seed crystal. The following processing is performed in the SEG of the single crystal Si. The semiconductor substrate 10 is placed in a processing chamber, and a source gas is supplied. Silane (SiH₄) or dichlorosilane (SiH₂Cl₂) or the like is used as the source gas. The conditions for the pressure, the temperature, and the carrier gas are the same as those in the SEG described above. Here, no dopant gas is introduced during the film formation of Si. Facets of single crystal Si are formed in the drain region 23 and the drain region 33.

After the drain region 23 and the drain region 33 are formed, a resist (not shown) is formed by using a known lithography technique at several times, and this resist is used as a mask to dope the drain region 23 of the first transistor Tr1 shown in FIG. 13A with phosphorus or arsenic, and dope the drain region 33 of the second transistor Tr2 shown in FIG. 13B with boron. The doping of phosphorus, arsenic, or boron is performed using a known ion implantation technique. Phosphorus, arsenic, or boron is doped at a concentration of, for example, about 1×10²⁰ atoms/cm³.

Next, as shown in FIGS. 1B-1E, FIGS. 2B-2C, and FIGS. 3B, and 4B, after a fifth insulating film 24 is formed, an insulating film is formed, and chemical mechanical polishing is performed to flatten the upper surface of the insulating film until at least the upper surface of the dummy gate 14 is exposed. Next, an insulating material and a conductive material are embedded in a groove formed by selectively the dummy gate 14, thereby forming the gate insulating films 20a, 30a, 40a, and 50a and the gate electrodes 20, 30, 40, and 50. Next, after an interlayer insulating film 25 is formed, contact plugs 26a, 26b, 36a, 36b, 46a, 46b, 56a, and 56b and wirings 28a, 28b, 38a, 38b, 48a, 48b, 58a, and 58b are formed. Through the above steps, the semiconductor device according to the embodiment is manufactured.

The manufacturing method described above is an example, and various modifications are possible. For example, the order of the steps for forming the source regions 22, 32, 42, and 52 and the drain regions 23, 33, 43, and 53 may be exchanged. Also, a halo and a Lightly Doped Drain (LDD) may be added to the source regions 22, 32, 42, and 52 and the drain regions 23, 33, 43, and 53.

As above, DRAM is described as an example of the semiconductor device according to the embodiment, but the above description is merely one example and not intended to be limited to DRAM. Memory devices other than DRAM, such as static random-access memory (SRAM), flash memory, erasable programmable read-only memory (EPROM), magnetoresistive random-access memory (MRAM), and phase-change memory for example can also be applied as the semiconductor device. Furthermore, devices other than memory, including logic ICs such as a microprocessor and an application-specific integrated circuit (ASIC), for example, are also applicable as the semiconductor device according to the foregoing embodiment.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a substrate; and
a first FinFET embedded in the substrate, the first FinFET including a gate electrode, one of source and drain and the other of source and drain;
wherein the one of source and drain comprises a Si-based compound and the other of source and drain comprises Si without the Si-based compound.

2. The apparatus of claim 1, wherein the one of source and drain of the first FinFET has a monocrystalline Si-based compound; and
wherein the other of source and drain of the first FinFET has a monocrystalline Si.

3. The apparatus of claim 1, wherein the one of source and drain of the first FinFET comprises SiGe as the Si-based compound.

4. The apparatus of claim 1, wherein both of source and drain of the first FinFET are doped with P-type impurity, respectively.

5. The apparatus of claim 4, wherein the impurity concentration of the one Of source and drain of the first FinFET is greater than the impurity concentration of the other of source and drain of the first FinFET.

6. The apparatus of claim 5, wherein the impurity concentration gradient at an edge of the one of source and drain of the first FinFET is steeper than the impurity concentration gradient at an edge of the other of source and drain of the first FinFET.

7. The apparatus of claim 6, further comprising a second FinFET embedded in the substrate, the second FinFET including a gate electrode, one of source and drain and the other of source and drain;
wherein the other of source and drain of the second FinFET comprises Si without the Si-based compound and comprises at least one central pillar which is a portion of the substrate; and
wherein the one of source and drain of the second FinFET comprises the Si-based compound without a central pillar.

8. The apparatus of claim 7, wherein both of source and drain of the second FinFET are doped with N-type impurity, respectively.

9. The apparatus of claim 8, wherein the impurity concentration of the one of source and drain of the second FinFET is greater than the impurity concentration of the other of source and drain of the second FinFET.

10. The apparatus of claim 9, wherein the impurity concentration gradient at an edge of the one of source and drain of the second FinFET is steeper than the impurity concentration gradient at an edge of the other of source and drain of the second FinFET.

11. An apparatus comprising:
a substrate;
a first FinFET and a second FinFET in the substrate, each of the first FinFET and the second FinFET including a gate electrode, one of source and drain and the other of source and drain;
wherein the one of source and drain of the second FinFET comprises a Si-based compound and both of source and drain of the first FinFET and the other of source and drain of the second FinFET comprises Si without the Si-based compound; and
wherein each of the other of source and drain of the first FinFET and the other of source and drain of the second FinFET comprises at least one central pillar which is a portion of the substrate.

12. The apparatus of claim 11, wherein each of both of source and drain of the first FinFET and the other of source and drain of the second FinFET comprises a monocrystalline Si; and
wherein the one of source and drain of the second FinFET comprises a monocrystalline Si-based compound.

13. The apparatus of claim 11, wherein the one of source and drain of the second FinFET comprises SiGe as the Si-based compound.

14. The apparatus of claim 11, wherein both of source and drain of the first FinFET are doped with N-type impurity, respectively; and
wherein both of source and drain of the second FinFET are doped with P-type impurity, respectively.

15. The apparatus of claim 14, wherein the impurity concentration of the one of source and drain of the first FinFET is greater than the impurity concentration of the other of source and drain of the first FinFET.

16. The apparatus of claim 15, wherein the impurity concentration of the one of source and drain of the second FinFET is greater than the impurity concentration of the other of source and drain of the second FinFET.

17. The apparatus of claim 16, wherein the impurity concentration gradient at an edge of the one of source and drain of the first FinFET is steeper than the impurity concentration gradient at an edge of the other of source and drain of the first FinFET; and
wherein the impurity concentration gradient at an edge of the one of source and drain of the second FinFET is steeper than the impurity concentration gradient at an edge of the other of source and drain of the second FinFET.

18. An apparatus comprising:
a substrate;
a first FinFET and a second FinFET in the substrate, each of the first FinFET and the second FinFET including a gate electrode, one of source and drain and the other of source and drain;
wherein the one of source and drain of the second FinFET comprises a Si-based compound and both of source and drain of the first FinFET and the other of source and drain of the second FinFET comprises Si without the Si-based compound;
wherein the one of source and drain of the second FinFET comprises an epitaxial monocrystalline Si-based compound; and
wherein both of source and drain of the first FinFET and the other of source and drain of the second FinFET comprise an epitaxial monocrystalline Si.

19. The apparatus of claim 18, wherein the one of source and drain of the first FinFET comprises Si with in-situ doped N-type impurity;
wherein the one of source and drain of the second FinFET comprises a Si-based compound with in-situ doped P-type impurity;
wherein the other of source and drain of the first FinFET comprises Si with ion implanted N-type impurity; and
wherein the other of source and drain of the second FinFET comprises Si with ion implanted P-type impurity.

20. The apparatus of claim 18, wherein each of the other of source and drain of the first FinFET and the other of source and drain of the second FinFET comprises at least one central pillar which is a portion of the substrate.
